(19) United States
(12) Patent Application Publication
(10) Pub. No.: US 2026/0190622 A1
(43) Pub. Date: Jul. 2, 2026

(54) DISPLAY APPARATUS AND METHOD OF MANUFACTURING THE SAME

(71) Applicant: LG Display Co., Ltd., Seoul (KR)

(72) Inventors: Hee Young CHAE, Paju-si (KR); Jong Sin PARK, Paju-si (KR); Sung Wook CHOI, Paju-si (KR); You Kyung SEO, Paju-si (KR)

(73) Assignee: LG Display Co., Ltd., Seoul (KR)

(21) Appl. No.: 19/251,639

(22) Filed: Jun. 26, 2025

(30) Foreign Application Priority Data
Dec. 30, 2024 (KR) 10-2024-0200501

(51) Int. Cl. H10K 59/121; H10K 59/12; H10K 59/122; H10K 59/131; H10K 59/38

(52) U.S. Cl. CPC H10K 59/1213; H10K 59/1201; H10K 59/122; H10K 59/131; H10K 59/38

(57) ABSTRACT

A display apparatus includes a color filter layer disposed on a substrate, a lower passivation layer disposed on the color filter layer, a driving transistor disposed on the lower passivation layer, a buffer layer disposed on the driving transistor, a metal layer disposed on the buffer layer, an anode electrode layer disposed on the metal layer and connected to the metal layer, a bank layer disposed on the anode electrode layer and including an opening portion exposing a portion of the anode electrode layer, an emission layer disposed on the anode electrode layer, and a cathode electrode layer disposed on the emission layer.

### CROSS-REFERENCE TO RELATED APPLICATION

This application claims the benefit of Korean Patent Application No. 10-2024-0200501 filed on Dec. 30, 2024, which is hereby incorporated by reference as if fully set forth herein.

### BACKGROUND

### Field of the Disclosure

The present disclosure relates to a display apparatus and a method of manufacturing the same.

### Discussion of the Related Art

As information technology advances, the market for display apparatuses which are connection mediums connecting a user with information is growing. Therefore, the use of display apparatuses such as light emitting display apparatuses, quantum dot display (QDD) apparatuses, and liquid crystal display (LCD) apparatuses is increasing.

The display apparatuses described above include a display panel which includes a plurality of subpixels, a driver which outputs a driving signal for driving the display panel, and a power supply which generates power which is to be supplied to the display panel or the driver.

In such display apparatuses, when the driving signal (for example, a scan signal and a data signal) is supplied to each of the subpixels provided in the display panel, a selected subpixel may transmit light or may self-emit light, and thus, an image may be displayed.

### SUMMARY

The present disclosure provides a display apparatus which may solve a problem of an increase in front temperature, may reduce a contact resistance when manufacturing a display panel, and may have a low reflectance. Also, the present disclosure provides a display apparatus which may improve an afterimage to enhance display quality, based on a high transmittance and a low reflectance. Also, the present disclosure provides a method of manufacturing a display apparatus, which may simplify a manufacturing process, based on a lift-off process and mask reduction technology.

The present disclosure may provide a display apparatus including: a color filter layer disposed on a substrate; a lower passivation layer disposed on the color filter layer; a driving transistor disposed on the lower passivation layer; a buffer layer disposed on the driving transistor; a first metal layer disposed on the buffer layer; an anode electrode layer disposed on the first metal layer and connected to the first metal layer; a bank layer disposed on the anode electrode layer and including an opening portion exposing a portion of the anode electrode layer; an emission layer disposed on the anode electrode layer; and a cathode electrode layer disposed on the emission layer.

The driving transistor may include: a first gate metal layer disposed on the lower passivation layer and defined as a gate electrode layer; a gate insulation layer disposed on the first gate metal layer; a semiconductor layer disposed on the gate insulation layer; a second gate metal layer disposed on the lower passivation layer and contacting a first electrode region of the semiconductor layer defined as a first electrode; and a third gate metal layer disposed on the lower passivation layer and contacting a second electrode region of the semiconductor layer defined as a second electrode.

The second gate metal layer may be connected to the first metal layer through a contact hole included in the buffer layer.

The display apparatus may further include an upper passivation layer disposed on the buffer layer, wherein the first metal layer may be connected to the anode electrode layer through a contact hole included in the upper passivation layer.

The first metal layer may directly surface-contact the anode electrode layer without a contact hole.

The color filter layer may include a first color filter layer and a second color filter layer overlapping each other in a region where the driving transistor is disposed.

The display apparatus may further include a plurality of pads disposed on the buffer layer and enabling an electrical connection with an external circuit, wherein the plurality of pads may include: a second metal layer and a third metal layer disposed on the buffer layer and spaced apart from each other; and a second anode electrode layer and a third anode electrode layer disposed on the second metal layer and the third metal layer and spaced apart from each other.

A method of manufacturing a display apparatus according to another embodiment of the present disclosure may include: defining a pad region, an emission region, and a circuit region on a sacrificial substrate; forming a first sacrificial layer, a second sacrificial layer, and a bank layer on the sacrificial substrate including the pad region, the emission region, and the circuit region; forming an anode electrode layer on the bank layer and dividing the anode electrode layer into a first anode electrode layer disposed in the emission region and the circuit region and a second anode electrode layer and a third anode electrode layer each disposed in the pad region; respectively forming a first metal layer, a second metal layer, and a third metal layer in the first anode electrode layer, the second anode electrode layer, and the third anode electrode layer; forming a buffer layer on the first metal layer, the second metal layer, and the third metal layer; forming a driving transistor on the buffer layer included in the circuit region; forming a lower passivation layer on the buffer layer including the pad region, the emission region, and the circuit region; forming a color filter layer on the lower passivation layer including the emission region and the circuit region; forming a filling layer on the color filter layer and the lower passivation layer including the pad region, the emission region, and the circuit region; forming a substrate on the filling layer including the pad region, the emission region, and the circuit region; vertically reversing the substrate and the sacrificial substrate, separating the first sacrificial layer and the second sacrificial layer, and removing the second sacrificial layer to expose the bank layer disposed on the substrate; performing patterning through the bank layer so that the first anode electrode layer, the second anode electrode layer, and the third anode electrode layer are exposed on the substrate; forming an emission layer on the first anode electrode layer; and forming a cathode electrode layer on the emission layer.

The driving transistor may include: a first gate metal layer disposed on the lower passivation layer and defined as a gate electrode layer; a gate insulation layer disposed on the first gate metal layer; a semiconductor layer disposed on the gate insulation layer; a second gate metal layer disposed on the lower passivation layer and contacting a first electrode region of the semiconductor layer defined as a first electrode; and a third gate metal layer disposed on the lower passivation layer and contacting a second electrode region of the semiconductor layer defined as a second electrode.

The pad region may further include a plurality of pads disposed on the buffer layer and enabling an electrical connection with an external circuit, wherein the plurality of pads may include: a second metal layer and a third metal layer disposed on the buffer layer and spaced apart from each other; and a second anode electrode layer and a third anode electrode layer disposed on the second metal layer and the third metal layer and spaced apart from each other.

The present disclosure provides a display apparatus which may have a low reflectance even without using a black matrix or a black bank layer (a bank layer of black color). Also, the present disclosure provides a display apparatus which may solve a problem of an increase in front temperature, may reduce a contact resistance when manufacturing a display panel. Also, the present disclosure provides a display apparatus which may improve an afterimage to enhance display quality, based on a high transmittance and a low reflectance. Also, the present disclosure provides a method of manufacturing a display apparatus, which may simplify a manufacturing process, based on mask reduction technology and a lift-off process for removing a sacrificial substrate used as a base substrate.

### BRIEF DESCRIPTION OF THE DRAWINGS

The accompanying drawings, which are included to provide a further understanding of the present disclosure and are incorporated in and constitute a part of this application, illustrate example embodiment(s) of the present disclosure and together with the description serve to explain the principles of the present disclosure. In the drawings:

FIG. 1 is a block diagram schematically illustrating a light emitting display apparatus according to example embodiments;

FIGS. 2 and 3 are diagrams for describing an example configuration of a gate driver of a gate in panel (GIP) type;

FIG. 4 is a diagram illustrating a cross-sectional surface of a display panel according to a first example embodiment;

FIGS. 5 to 17 are diagrams for describing a method of manufacturing the display panel illustrated in FIG. 4;

FIG. 18 is a diagram illustrating a cross-sectional surface of a display panel according to a second example embodiment;

FIG. 19 is a diagram illustrating a cross-sectional surface of a display panel according to a third example embodiment; and

FIG. 20 is a diagram for describing a process implemented by modification of the first example embodiment, according to a third example embodiment.

### DETAILED DESCRIPTION

Hereinafter, the present disclosure will be described more fully with reference to the accompanying drawings, in which example embodiments of the disclosure are shown. The disclosure may, however, be embodied in many different forms and should not be construed as being limited to the embodiments set forth herein; rather, these embodiments are provided so that this disclosure will be thorough and complete, and will fully convey the concept of the disclosure to those skilled in the art.

A display apparatus according to the present disclosure may be applied to televisions (TVs), video players, personal computers (PCs), home theaters, electronic devices for vehicles, and smartphones, but is not limited thereto. The display apparatus according to the present disclosure may be implemented as a light emitting display apparatus, a quantum dot display (QDD) apparatus, or a liquid crystal display (LCD) apparatus. Hereinafter, for convenience of description, a light emitting display apparatus self-emitting light by using an inorganic light emitting diode or an organic light emitting diode will be described for example.

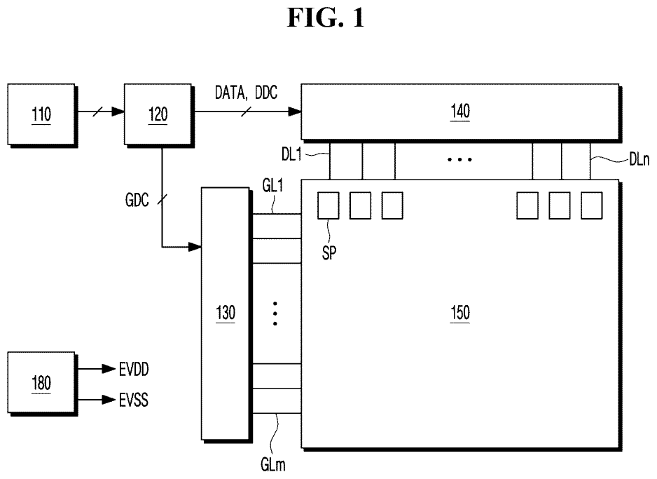

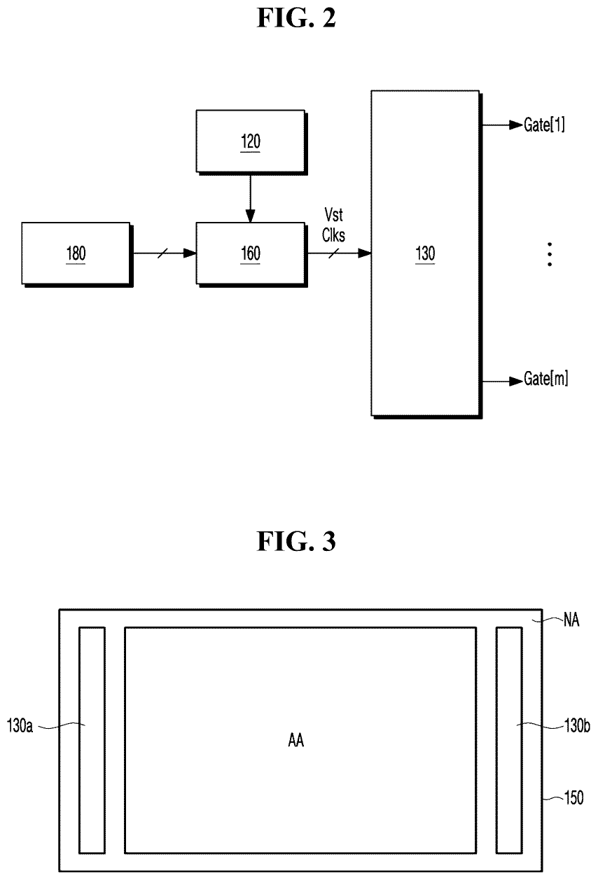

FIG. 1 is a block diagram schematically illustrating a light emitting display apparatus according to example embodiments, and FIGS. 2 and 3 are diagrams for describing an example configuration of a gate driver of a gate in panel (GIP) type.

As illustrated in FIGS. 1 to 3, a light emitting display apparatus according to an example embodiment of the present disclosure may include a timing controller (a timing control circuit) 120, a gate driver (a gate driving circuit) 130, a data driver (a data driving circuit) 140, a display panel 150, and a power supply (a power supply circuit) 180.

A video supply unit 110 (a set or a host system) may output a video data signal supplied from the outside or an image data signal stored in an internal memory thereof. The video supply unit 110 may supply a data signal and the various driving signals to the timing controller 120.

The timing controller 120 may output a gate timing control signal GDC for controlling an operation timing of the gate driver 130, a data timing control signal DDC for controlling an operation timing of the data driver 140, and various synchronization signals (a vertical synchronization signal Vsync and a horizontal synchronization signal Hsync). The timing controller 120 may provide the data driver 140 with the data timing control signal DDC and a data signal DATA supplied from the video supply unit 110. The timing controller 120 may be implemented as an integrated circuit (IC) type and may be mounted on a printed circuit board (PCB), but is not limited thereto.

The gate driver 130 may output a gate signal (or a gate voltage) in response to the gate timing control signal GDC supplied from the timing controller 120. The gate driver 130 may supply the gate signal to a plurality of subpixels, included in the display panel 150, through a plurality of gate lines GL1 to GLm. The gate driver 130 may be implemented as an IC type or may be directly provided on the display panel 150 in a gate in panel (GIP) type, but is not limited thereto. Hereinafter, for convenience of description, as in FIGS. 2 and 3, a gate driver of a GIP type will be described for example.

The gate driver 130 may include a plurality of shift registers 130a and 130b which are provided as a GIP type at one side and the other side of a non-display area NA of the display panel 150. The shift registers 130a and 130b may be provided as a thin film type in the non-display area NA of the display panel 150, based on a GIP type. The gate driver 130 may output gate signals Gate[1] to Gate[m] for turning on or off transistors formed in a display area AA of the display panel 150.

The gate driver 130 may operate based on signals and voltages output from the timing controller 120, the power supply 180, and the level shifter 160. The level shifter 160 may generate gate control signals needed for driving of the gate driver 130, 130a, and 130b, based on the signals and the voltages output from the timing controller 120 and the power supply 180.

In response to the data timing control signal DDC supplied from the timing controller 120, the data driver 140 may sample and latch the data signal DATA, convert a digital data signal into an analog data voltage, based on a gamma reference voltage, and output the analog data voltage. The data driver 140 may respectively supply data voltages to the subpixels of the display panel 150 through a plurality of data lines DL1 to DLn. The data driver 140 may be implemented as an IC type or may be mounted on the display panel 150 or a PCB, but is not limited thereto.

The power supply 180 may generate a high-level voltage and a low-level voltage, based on an external input voltage supplied from the outside, and may output the high-level voltage and the low-level voltage through a high-level voltage line EVDD and a low-level voltage line EVSS. The power supply 180 may generate and output a voltage needed for driving of the gate driver 130 or a voltage needed for driving of the data driver 140, in addition to the high-level voltage and the low-level voltage.

The display panel 150 may be manufactured based on a substrate, having stiffness or flexibility, such as glass, silicone, or polyimide. The display panel 150 may include a plurality of subpixels SP for displaying an image. The subpixel SP may self-emit light toward an upper surface, a lower substrate, or the upper substrate and the lower substrate of the display panel 150. The subpixel SP may emit light having one color of red, green, blue, and white. The display panel 150 may display an image, based on a pixel configured with a red subpixel, a green subpixel, and a blue subpixel or a pixel configured with a red subpixel, a green subpixel, a blue subpixel, and a white subpixel.

In the above description, each of the timing controller 120, the gate driver 130, and the data driver 140 has been described as an individual element. However, based on an implementation type of the light emitting display apparatus, one or more of the timing controller 120, the gate driver 130, and the data driver 140 may be integrated into one IC.

FIG. 4 is a diagram illustrating a cross-sectional surface of a display panel according to a first example embodiment.

As illustrated in FIG. 4, the display panel according to the first example embodiment may include a pad region PDA, an emission region EMA, and a circuit region CRA, which are defined on a substrate SUB. The pad region PDA may be a region where pads PAD1 and PAD2 for implementing an electrical connection with an external circuit board are disposed. The emission region EMA may be a region where a light emitting diode OLED emitting light is disposed. The circuit region CRA may be a region where a driving transistor DT generating a driving current to be applied to the light emitting diode OLED is disposed.

The display panel, including the pad region PDA, the emission region EMA, and the circuit region CRA each defined on the substrate SUB, may have the following an inter-layer structure. The substrate SUB may be selected as transparent polyimide (PI) or a hard coating layer as well as glass.

A filling layer FIL may be disposed on the substate SUB. The filling layer FIL may be selected as an organic layer including an overcoat layer OC or an adhesive/tacky layer including an optically clear adhesive film (OCA) or a pressure sensitive adhesive (PSA).

A color filter layer CF1 and CF2 may be disposed on the filling layer FIL. The color filter layer CF1 and CF2 may include a material (for example, a pigment) which may convert light, emitted from the light emitting diode OLED, into light of another color. For example, the color filter layer CF1 and CF2 may include a total of three color filter layers which may convert white light into light of a first color (for example, red), a second color (for example, blue), or a third color (for example, green). That is, in FIG. 4, only a first color filter layer CF1 and a second color filter layer CF2 are illustrated, and a third color filter layer is not illustrated. Here, one color filter layer may be disposed in one emission region EMA. Furthermore, in FIG. 4, an example is illustrated where the color filter layer CF1 and CF2 includes the first color filter layer CF1 and the second color filter layer CF2, and partial regions thereof overlap each other in the circuit region CRA. An overlap portion between the first color filter layer CF1 and the second color filter layer CF2 may replace a black matrix layer. However, this may be merely one example embodiment, the first and second color filter layers CF1 and CF2 may not overlap each other, and the black matrix layer may be disposed therebetween.

A lower passivation layer (a second passivation layer) PAS2 may be disposed on the color filter layer CF1 and CF2. The lower passivation layer PAS2 may be selected as an inorganic material including silicon nitride or silicon oxide.

A gate metal layer GAT1 to GAT3 may be disposed on the lower passivation layer PAS2. The gate metal layer GAT1 to GAT3 may include a first gate metal layer GAT1, a second gate metal layer GAT2, and a third gate metal layer GAT3. The first gate metal layer GAT1 may be a gate electrode layer of the driving transistor DT, and the second gate metal layer GAT2 and the third gate metal layer GAT3 may respectively be a first electrode layer and a second electrode layer of the driving transistor DT. An example where the gate metal layer GAT1 to GAT3 is disposed in only the circuit region CRA is illustrated, but the present disclosure is not limited thereto.

A gate insulation layer GI may be disposed on the first gate metal layer GAT1. The gate insulation layer GI may be disposed between a semiconductor layer SEM and the first gate metal layer GAT1 so that a channel region is formed in the semiconductor layer SEM disposed thereunder. The semiconductor layer SEM may be disposed on the second gate metal layer GAT2 and the third gate metal layer GAT3. The semiconductor layer SEM may be selected as an oxide semiconductor (for example, indium gallium zinc oxide (IGZO)), but is not limited thereto.

The semiconductor layer SEM may include the channel region which overlaps and does not contact the first gate metal layer GAT1, a first electrode region (a drain region) which partially contacts and partially overlaps the second gate metal layer GAT2, and a second electrode region (a source region) which partially contacts and partially overlaps the third gate metal layer GAT3. In the semiconductor layer SEM, the first electrode region (the drain region) and the second electrode region (the source region) except the channel region may have conductive properties instead of semiconductor properties, based on a conduction-enabling process. Therefore, the first electrode region (the drain region) and the second electrode region (the source region) may be defined as a conductive semiconductor layer. The conduction-enabling process may include a plasma process, a dry etching process, or a material (for example, hydrogen) doping process, and this may be selected as one process of easy processes, based on a manufacturing method. Also, an example where the semiconductor layer SEM is disposed in only the circuit region CRA is illustrated, but the present disclosure is not limited thereto.

A buffer layer BUF may be disposed on the semiconductor layer SEM. The buffer layer BUF may be selected as an inorganic material including silicon nitride or silicon oxide.

A metal layer LSM1 to LSM3 may be disposed on the buffer layer BUF. The metal layer LSM1 to LSM3 may include a first metal layer LSM1, a second metal layer LSM2, and a third metal layer LSM3, which are disposed apart from one another. The first metal layer LSM1 may be disposed in the circuit region CRA, and the second metal layer LSM2 and the third metal layer LSM3 may be disposed in the pad region PDA. The first metal layer LSM1 may be a light blocking layer which prevents or suppresses external light from being irradiated onto the semiconductor layer SEM included in the driving transistor DT. The second metal layer LSM2 and the third metal layer LSM3 may be a first pad electrode layer included in the pads PAD1 and PAD2. Also, the first metal layer LSM1 may be electrically connected to the second gate metal layer (first electrode layer) GAT2 included in the driving transistor DT through a contact hole of the buffer layer BUF.

An upper passivation layer (a first passivation layer) PAS1 may be disposed on the metal layer LSM1 to LSM3. The upper passivation layer PAS1 may be selected as an inorganic material including silicon nitride or silicon oxide. The upper passivation layer PAS1 and the lower passivation layer PAS2 may be selected as the same material, but are not limited thereto and may be selected as different materials. The upper passivation layer PAS1 may expose the second metal layer LSM2 and the third metal layer LSM3.

An anode electrode layer AN1 to AN3 may be disposed on the upper passivation layer PAS1. The anode electrode layer AN1 to AN3 may be configured as a single layer or a multilayer. The anode electrode layer AN1 to AN3 may include a first anode electrode layer AN1, a second anode electrode layer AN2, and a third anode electrode layer AN3, which are disposed apart from one another. The first anode electrode layer AN1 may be disposed in the emission region EMA and the circuit region CRA, and the second anode electrode layer AN2 and the third anode electrode layer AN3 may be disposed in the pad region PDA. The first anode electrode layer AN1 may be an anode electrode layer included in the light emitting diode OLED, and the second anode electrode layer AN2 and the third anode electrode layer AN3 may be a second pad electrode layer included in the pads PAD1 and PAD2. The first anode electrode layer AN1 may be electrically connected to the first metal layer LSM1 through a contact hole of the upper passivation layer PAS1. The second anode electrode layer AN2 may be electrically connected to the second metal layer LSM2, and the third anode electrode layer AN3 may contact the third metal layer LSM3 to be electrically connected thereto.

A bank layer BNK may be disposed on the upper passivation layer PAS1. The bank layer BNK may include an opening portion which exposes the first anode electrode layer AN1 in the emission region EMA and may include a pattern part which exposes the second anode electrode layer AN2 and the third anode electrode layer AN3 in the pad region PDA.

An emission layer EML may be disposed on the first anode electrode layer AN1 exposed through the bank layer BNK. The emission layer EML may emit white light, and light may be converted into light of a specific color by the color filter layer and may be irradiated toward the substrate SUB. The emission layer EML may emit white light, based on one emission layer, or may emit white light, based on at least two emission layers. In FIG. 4, an example where the emission layer EML is disposed on only the exposed first anode electrode layer AN1 is illustrated. However, the emission layer EML may be disposed on the bank layer BNK disposed in the emission region EMA and the circuit region CRA.

A cathode electrode layer CAT may be disposed on the bank layer BNK and the emission layer EML. The cathode electrode layer CAT may be configured as a single layer or a multilayer. An example where the cathode electrode layer CAT is disposed in only the emission region EMA and the circuit region CRA is illustrated. However, the cathode electrode layer CAT may be electrically connected to a low-level voltage line in a region (not shown).

An encapsulation layer ENC may be disposed on the bank layer BNK. The encapsulation layer ENC may be disposed in the emission region EMA and the circuit region CRA to expose the pad region PDA. The encapsulation layer ENC may be selected as a composite sheet layer including a sealing layer and a metal layer, but is not limited thereto.

Hereinafter, a method of manufacturing a display panel according to a first example embodiment will be described.

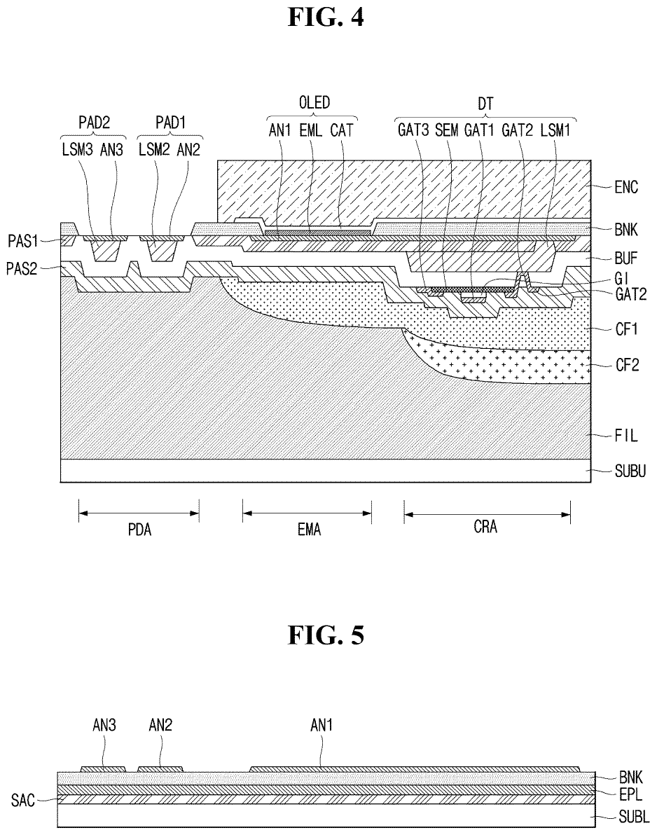

FIGS. 5 to 17 are diagrams for describing a method of manufacturing the display panel illustrated in FIG. 4.

As illustrated in FIG. 5, a first sacrificial layer SAC, a second sacrificial layer EPL, a bank layer BNK, and an anode electrode layer AN1 to AN3 may be successively formed on a sacrificial substrate SUBL. Subsequently, the anode electrode layer AN1 to AN3 may be patterned by using a first mask so that the anode electrode layer AN1 to AN3 is divided into a first anode electrode layer AN1, a second anode electrode layer AN2, and a third anode electrode layer AN3, which are spaced apart from one another. Here, the first sacrificial layer SAC may be selected as amorphous silicon (a-Si), the second sacrificial layer EPL may be selected as indium tin oxide (ITO), and the bank layer BNK may be selected as silicon oxide (SiO₂), but the present disclosure is not limited thereto. Here, the sacrificial substrate SUBL may include copper (Cu) or aluminum (Al) as well as ITO.

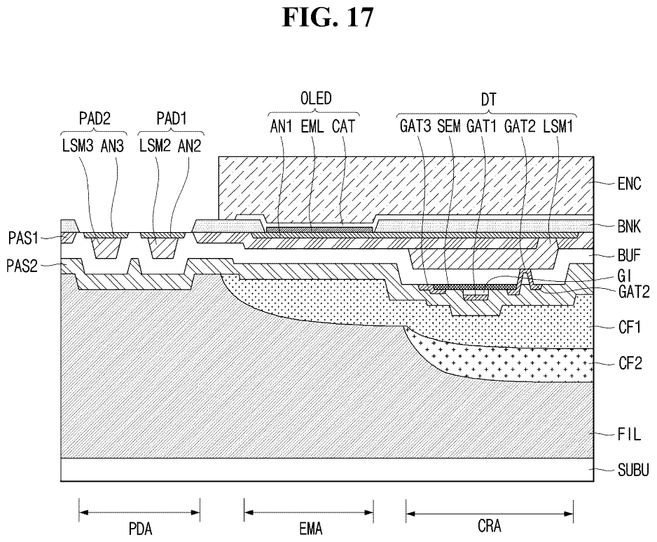

Furthermore, as in FIG. 4, a pad region PDA, an emission region EMA, and a circuit region CRA may be defined on the sacrificial substrate SUBL, but for convenience of description, this may refer to FIG. 17 (or FIG. 4) where a process is completed.

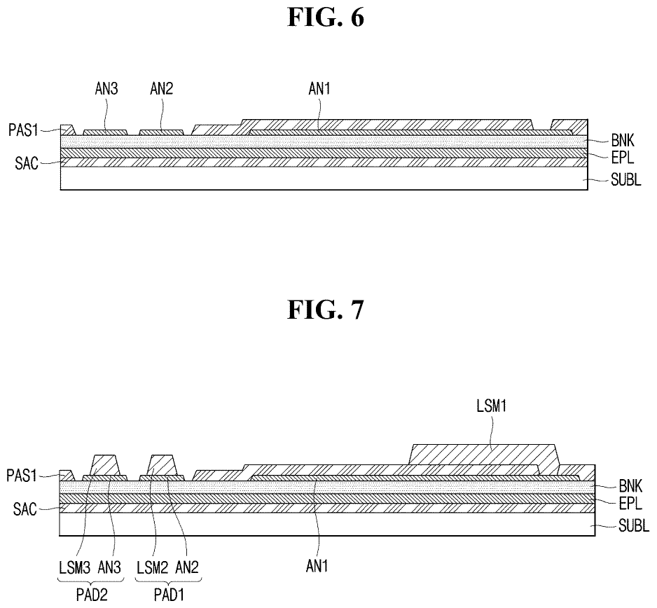

As illustrated in FIG. 6, a first passivation layer (an upper passivation layer) PAS1 may be formed on the bank layer BNK. Subsequently, the first passivation layer PAS1 may be patterned by using a second mask so that a partial region of the first anode electrode layer AN1 and all regions of the second anode electrode layer AN2 and the third anode electrode layer AN3 are exposed through the first passivation layer PAS1.

As illustrated in FIG. 7, a metal layer LSM1 to LSM3 may be formed on the first passivation layer PAS1. Subsequently, the metal layer LSM1 to LSM3 may be patterned by using a third mask so that the metal layer LSM1 to LSM3 is divided into a first metal layer LSM1, a second metal layer LSM2, and a third metal layer LSM3, which are spaced apart from one another along a region. Here, the first metal layer LSM1 may be a light blocking layer, the second metal layer LSM2, the third metal layer LSM3, and the pads PAD1 and PAD2 may be exposed along with the second anode electrode layer AN2 and the third anode electrode layer AN3.

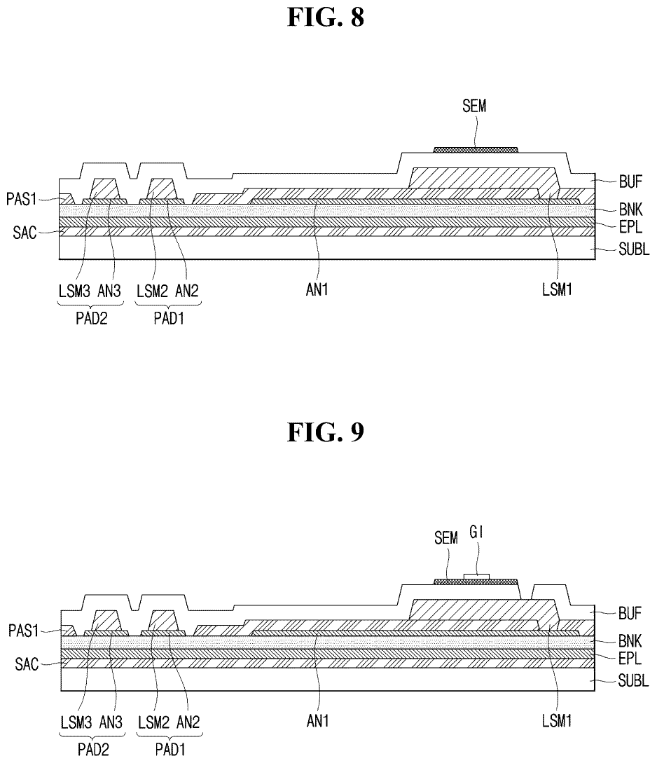

As illustrated in FIG. 8, a buffer layer BUF and a semiconductor layer SEM may be formed on the first passivation layer PAS1. Subsequently, patterning may be performed by using a fourth mask so that a portion of the semiconductor layer SEM is disposed in a region corresponding to the first metal layer LSM1. Here, the fourth mask may be selected as a halftone mask where a pattern condition may differ for each region.

As illustrated in FIG. 9, a gate insulation layer GI may be formed on the buffer layer BUF. Subsequently, a contact hole may be formed in the buffer layer BUF adjacent to the semiconductor layer SEM, and patterning may be performed by using a fifth mask so that the gate insulation layer GI is disposed in only a channel region overlapping the semiconductor layer SEM.

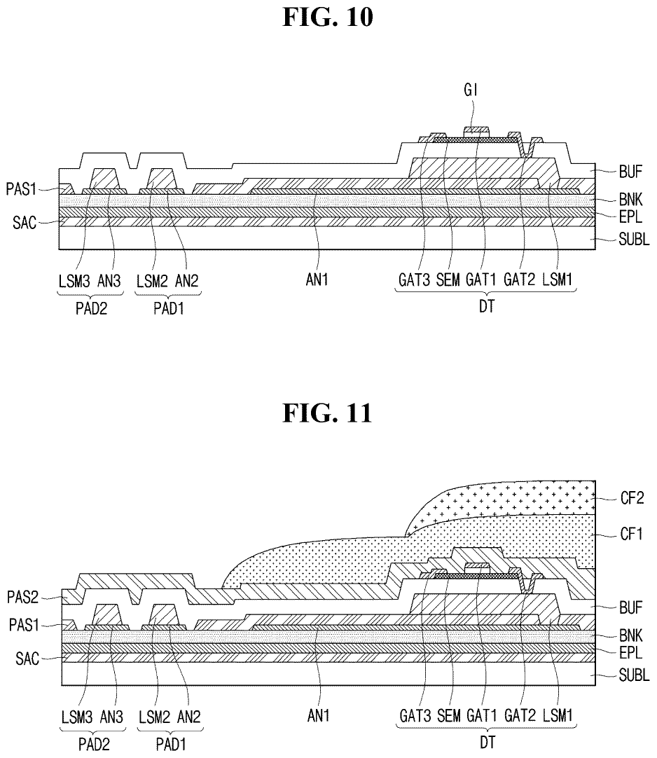

As illustrated in FIG. 10, a gate metal layer Gat1 to Gat3 may be formed on the buffer layer BUF and the gate insulation layer GI. Subsequently, the gate metal layer GAT1 to GAT3 may be patterned by using a sixth mask so that the gate metal layer GAT1 to GAT3 is divided into a first gate metal layer GAT1, a second gate metal layer GAT2, and a third gate metal layer GAT3, which are spaced apart from one another. Here, the second gate metal layer GAT2 may be electrically connected to the first metal layer LSM1 through the contact hole of the buffer layer BUF.

As illustrated in FIG. 11, a second passivation layer (a lower passivation layer) PAS2 and a color filter layer CF1 and CF2 may be formed on the buffer layer BUF. Although not shown, the color filter layer CF1 and CF2 may be patterned by using seventh to ninth masks so that only one color filter layer is disposed in one emission region. Here, the seventh mask may be used for patterning a first color filter layer CF1, the eighth mask may be used for patterning a second color filter layer CF2, and the ninth mask may be used for patterning a third color filter layer (not shown).

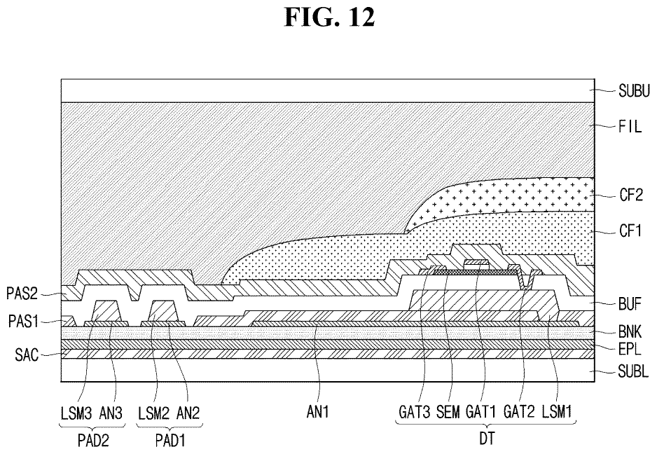

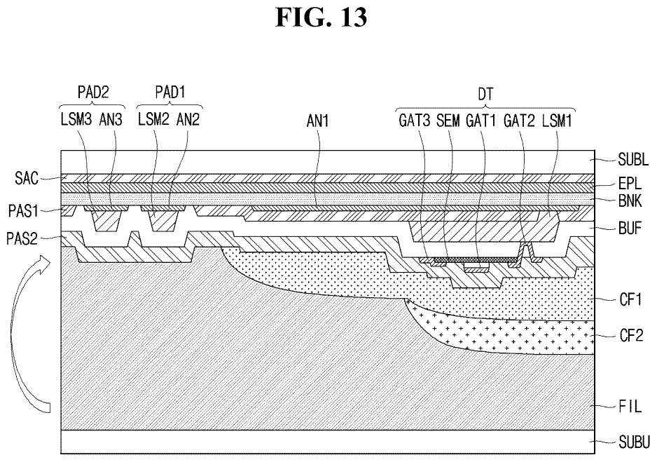

As illustrated in FIGS. 12 and 13, a filling layer FIL may be formed on the second passivation layer PAS2 and the color filter layer CF1 and CF2, and a substrate SUBU may be attached to the filling layer FIL. Subsequently, the substrate may be reversed (vertically reversed) so that the sacrificial substrate SUBL is upward raised, and the substrate SUBU is downward lowered. Here, a substrate (or glass) reverser may be used for upward raising the sacrificial substrate SUBL and downward lowering the substrate SUBU, but is not limited thereto.

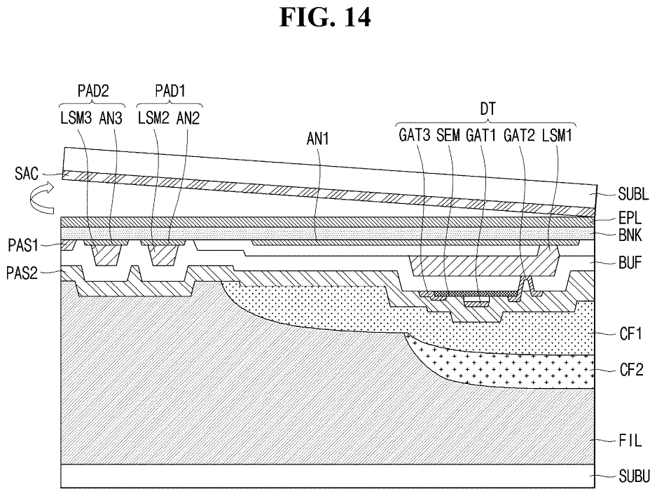

As illustrated in FIG. 14, a first sacrificial layer SAC and a second sacrificial layer EPL may be separated from each other so that the sacrificial substrate SUBL is removed from the substrate SUBU. The first sacrificial layer SAC and the second sacrificial layer EPL may be separated from each other through a laser lift-off process, but are not limited thereto. Subsequently, the second sacrificial layer EPL may be removed through etching, and the bank layer BNK may be exposed. Also, the sacrificial substrate SUBL including the first sacrificial layer SAC may be reused.

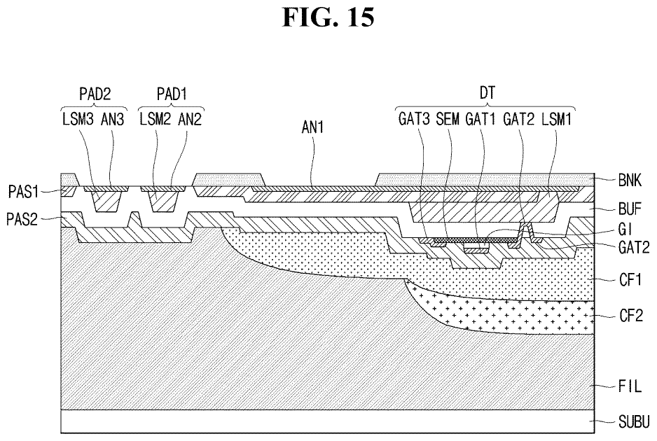

As illustrated in FIG. 15, the bank layer BNK may be patterned by using a tenth mask so that a partial region of the first anode electrode layer AN1 and all regions of the second anode electrode layer AN2 and the third anode electrode layer AN3 are exposed.

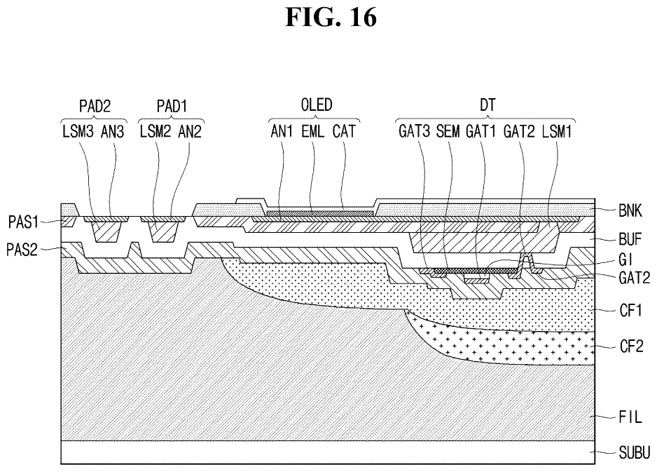

As illustrated in FIGS. 16 and 17, an emission layer EML may be formed on the first anode electrode layer AN1 exposed through the bank layer BNK, and a cathode electrode layer CAT may be formed on the emission layer EML. Subsequently, an encapsulation layer ENC may be formed on the bank layer BNK. The encapsulation layer ENC may cover the cathode electrode layer CAT and the bank layer BNK.

Through the process described above, pads PAD1 and PAD2 may be formed in a pad region PDA of the substrate SUBU, a light emitting diode OLED may be formed in the emission region EMA, and a driving transistor DT may be formed in a circuit region CRA.

Furthermore, according to the first example embodiment, an area of an upper surface of the metal layer LSM1 to LSM3 contacting the anode electrode layer AN1 to AN3 may be greater than that of a lower surface of the metal layer LSM1 to LSM3 contacting the buffer layer BUF. This may be because the metal layer LSM1 to LSM3 is formed on the anode electrode layer AN1 to AN3 disposed on the sacrificial substrate SUBL, but a process step after the sacrificial substrate SUBL and the substrate SUBU are reversed is performed via a process step described above. Also, a structure where an area of an upper surface is formed greater than that of a lower surface may be in another layer such as the color filter layer CF1 and CF2 or the semiconductor layer SEM as well as the metal layer LSM1 to LSM3 and the anode electrode layer AN1 to AN3. That is, the sacrificial substrate SUBL may be removed after a process for forming each layer on the sacrificial substrate SUBL is performed, and in a case where a subsequent process is performed on the substrate SUBU, a structural characteristic where an area of an upper surface is greater than that of a lower surface may be implemented as described above.

Moreover, according to the first embodiment, electrodes configuring a circuit (for example, a transistor and a capacitor) such as the driving transistor DT and a line connected to the electrodes may be covered by the first and second color filter layers CF1 and CF2 which are formed to overlap each other. That is, an electrode or a line for increasing a reflectance with external light may be covered by an overlap portion of the first and second color filter layers CF1 and CF2. As a result, the display panel according to the first embodiment may have a low reflectance even without using a black matrix or a black bank layer (a bank layer of black color), and thus, may improve an afterimage.

Moreover, according to the first embodiment, a circuit such as the driving transistor DT may not be formed just on the substrate SUBU and may be formed on the filling layer FIL, and thus, may solve a problem of an increase in front temperature of the display panel.

Hereinafter, a display panel according to another example embodiment will be described, and a difference with the first example embodiment will be mainly described to more clearly understand another example embodiment. Therefore, details which are not described below may refer to the first example embodiment.

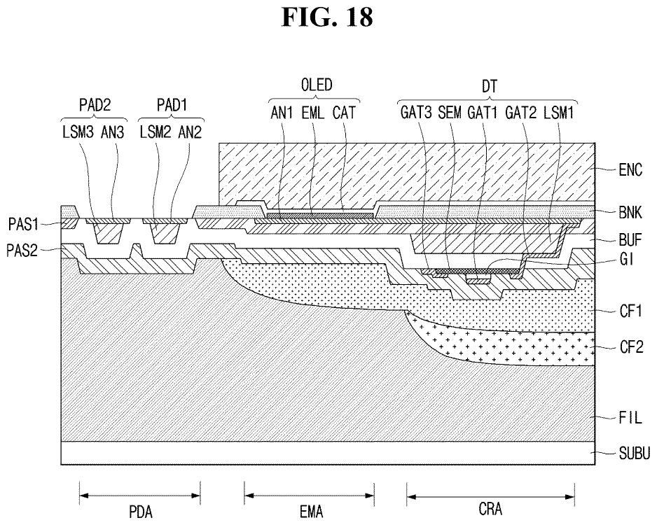

FIG. 18 is a diagram illustrating a cross-sectional surface of a display panel according to a second example embodiment.

As illustrated in FIG. 18, in the display panel according to the second example embodiment, a second gate metal layer (a first electrode layer) GAT2 included in a driving transistor DT may be directly connected to (contact) a first metal layer LSM1 and a first anode electrode layer AN1.

The second gate metal layer GAT2 may contact a first surface (a lower surface in the drawing) and a second surface (a side surface in the drawing) of the first metal layer LSM1 and may contact a first surface (a lower surface in the drawing) of the first anode electrode layer AN1. However, the second gate metal layer GAT2 may contact the first surface (the lower surface in the drawing) and a second surface (a side surface in the drawing) of the first anode electrode layer AN1 and may contact a first surface (a lower surface in the drawing) of a bank layer BNK.

As seen through a comparison of the first example embodiment of FIG. 4 and the second example embodiment of FIG. 18, the second gate metal layer GAT2 included in the driving transistor DT may be selected as one of structures indirectly or directly connected to the first anode electrode layer AN1.

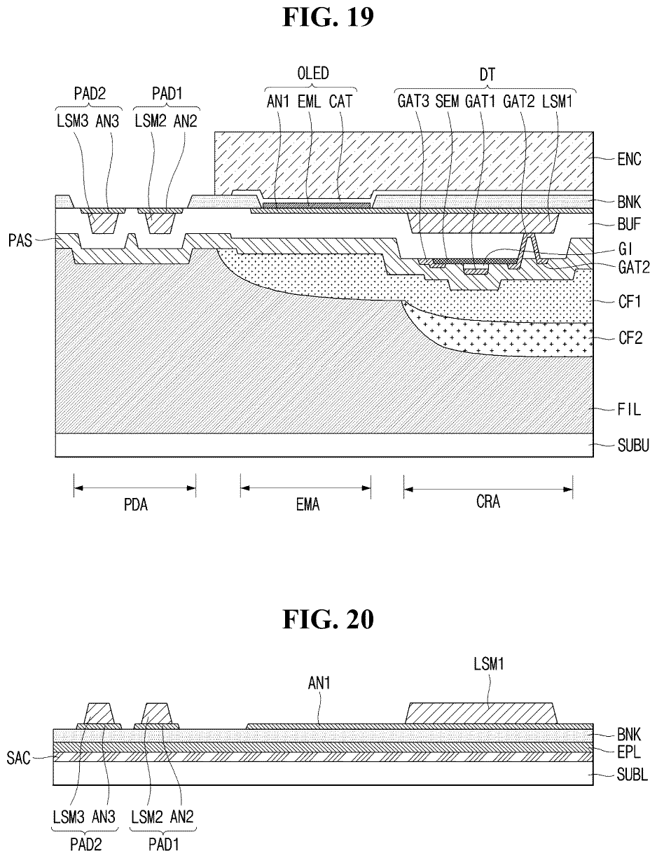

FIG. 19 is a diagram illustrating a cross-sectional surface of a display panel according to a third example embodiment, and FIG. 20 is a diagram for describing a process implemented by modification of the first example embodiment, according to a third example embodiment.

As illustrated in FIG. 19, in the display panel according to the third example embodiment, a first anode electrode layer AN1, a second anode electrode layer AN2, and a third anode electrode layer AN3 may be respectively disposed just on a first metal layer LSM1, a second metal layer LSM2, and a third metal layer LSM3. Therefore, the first metal layer LSM1 may directly surface-contact the first anode electrode layer AN1 without a contact hole, like the second metal layer LSM2, the third metal layer LSM3, the second anode electrode layer AN2, and the third anode electrode layer AN3.

As described above, when the first metal layer LSM1 directly surface-contacts the first anode electrode layer AN1 without a contact hole, a contact resistance may decrease more than a case where the first metal layer LSM1 directly surface-contacts the first anode electrode layer AN1 through the contact hole.

Moreover, according to the third example embodiment, a passivation layer (for example, the upper passivation layer (the first passivation layer) PAS1 of FIG. 4) disposed between the buffer layer BUF and the bank layer BNK may be omitted (removed), and only one passivation layer PAS may be provided between the buffer layer BUF and the bank layer BNK. To provide an additional description, as a passivation layer disposed between the buffer layer BUF and the bank layer BNK is removed, the metal layer LSM1 to LSM3 and the anode electrode layer AN1 to AN3 may have a structure (a low resistance structure for reducing a contact resistance) where layers surface-contact each other without a contact hole.

As illustrated in FIG. 20, according to the third example embodiment, the anode electrode layer AN1 to AN3 and the metal layer LSM1 to LSM3 may be successively formed on the bank layer BNK, and then, when patterning is performed by a halftone mask which allows the amount of exposure to differ for each region, the anode electrode layer AN1 to AN3 and the metal layer LSM1 to LSM3 may be formed to be spaced apart from each other. Accordingly, only the first anode electrode layer AN1 may remain in an emission region (or an opening portion), the first anode electrode layer AN1 and the first metal layer LSM1 may remain in a circuit region, and the second and third anode electrode layers AN2 and AN3 and the second and third metal layers LSM2 and LSM5 may remain in a pad region. To this end, a method which adjusts a width of a slit included in the halftone mask for each region or adjusts the number of slits for each region may be used.

As described above, in a case where the passivation disposed between the buffer layer BUF and the bank layer BNK is omitted and the halftone mask is used, a mask process may be simplified. For example, when it is assumed that a total of 10 masks are used in using a process according to the first embodiment, the mask process (mask reduction technology) may be simplified so that a total of 8 masks are used in using a process according to the third embodiment.

Hereinabove, the present disclosure provides a display apparatus which may have a low reflectance even without using a black matrix or a black bank layer (a bank layer of black color). Also, the present disclosure provides a display apparatus which may solve a problem of an increase in front temperature, may reduce a contact resistance when manufacturing a display panel. Also, the present disclosure provides a display apparatus which may improve an afterimage to enhance display quality, based on a high transmittance and a low reflectance. Also, the present disclosure provides a method of manufacturing a display apparatus, which may simplify a manufacturing process, based on mask reduction technology and a lift-off process for removing a sacrificial substrate used as a base substrate.

The effects according to the present disclosure are not limited to the above examples, and other various effects may be included in the specification.

While the present disclosure has been particularly shown and described with reference to example embodiments thereof, it will be understood by those of ordinary skill in the art that various changes in form and details may be made therein without departing from the spirit and scope of the present disclosure as may be defined, for example, by the following claims and their equivalents.

What is claimed is:

1. A display apparatus, comprising:
a color filter layer disposed on a substrate;
a lower passivation layer disposed on the color filter layer;
a driving transistor disposed on the lower passivation layer;
a buffer layer disposed on the driving transistor;
a first metal layer disposed on the buffer layer;
an anode electrode layer disposed on the first metal layer and connected to the first metal layer;
a bank layer disposed on the anode electrode layer and including an opening portion exposing a portion of the anode electrode layer;
an emission layer disposed on the anode electrode layer; and
a cathode electrode layer disposed on the emission layer.

2. The display apparatus of claim 1, wherein the driving transistor comprises:
a first gate metal layer disposed on the lower passivation layer and defined as a gate electrode layer;
a gate insulation layer disposed on the first gate metal layer;
a semiconductor layer disposed on the gate insulation layer;
a second gate metal layer disposed on the lower passivation layer and contacting a first electrode region of the semiconductor layer defined as a first electrode; and
a third gate metal layer disposed on the lower passivation layer and contacting a second electrode region of the semiconductor layer defined as a second electrode.

3. The display apparatus of claim 2, wherein the second gate metal layer is connected to the first metal layer through a contact hole included in the buffer layer.

4. The display apparatus of claim 2, further comprising an upper passivation layer disposed on the buffer layer, and
wherein the first metal layer is connected to the anode electrode layer through a contact hole included in the upper passivation layer.

5. The display apparatus of claim 2, wherein the first metal layer directly surface-contacts the anode electrode layer without a contact hole.

6. The display apparatus of claim 1, wherein the color filter layer comprises a first color filter layer and a second color filter layer overlapping each other in a region where the driving transistor is disposed.

7. The display apparatus of claim 1, further comprising a plurality of pads disposed on the buffer layer and enabling an electrical connection with an external circuit, and
wherein the plurality of pads comprise:
a second metal layer and a third metal layer disposed on the buffer layer and spaced apart from each other; and
a second anode electrode layer and a third anode electrode layer disposed on the second metal layer and the third metal layer and spaced apart from each other.

8. A method of manufacturing a display apparatus, the method comprising:
defining a pad region, an emission region, and a circuit region on a sacrificial substrate;
forming a first sacrificial layer, a second sacrificial layer, and a bank layer on the sacrificial substrate including the pad region, the emission region, and the circuit region;
forming an anode electrode layer on the bank layer and dividing the anode electrode layer into a first anode electrode layer disposed in the emission region and the circuit region and a second anode electrode layer and a third anode electrode layer each disposed in the pad region;
respectively forming a first metal layer, a second metal layer, and a third metal layer in the first anode electrode layer, the second anode electrode layer, and the third anode electrode layer;
forming a buffer layer on the first metal layer, the second metal layer, and the third metal layer;
forming a driving transistor on the buffer layer included in the circuit region;
forming a lower passivation layer on the buffer layer including the pad region, the emission region, and the circuit region;
forming a color filter layer on the lower passivation layer including the emission region and the circuit region;
forming a filling layer on the color filter layer and the lower passivation layer including the pad region, the emission region, and the circuit region;
forming a substrate on the filling layer including the pad region, the emission region, and the circuit region;
vertically reversing the substrate and the sacrificial substrate, separating the first sacrificial layer and the second sacrificial layer, and removing the second sacrificial layer to expose the bank layer disposed on the substrate;
performing patterning through the bank layer so that the first anode electrode layer, the second anode electrode layer, and the third anode electrode layer are exposed on the substrate;
forming an emission layer on the first anode electrode layer; and
forming a cathode electrode layer on the emission layer.

9. The method of claim 8, wherein the driving transistor comprises:
a first gate metal layer disposed on the lower passivation layer and defined as a gate electrode layer;
a gate insulation layer disposed on the first gate metal layer;
a semiconductor layer disposed on the gate insulation layer;
a second gate metal layer disposed on the lower passivation layer and contacting a first electrode region of the semiconductor layer defined as a first electrode; and
a third gate metal layer disposed on the lower passivation layer and contacting a second electrode region of the semiconductor layer defined as a second electrode.

10. The method of claim 8, wherein the pad region further comprises a plurality of pads disposed on the buffer layer and enabling an electrical connection with an external circuit, and
wherein the plurality of pads comprise:
a second metal layer and a third metal layer disposed on the buffer layer and spaced apart from each other; and
a second anode electrode layer and a third anode electrode layer disposed on the second metal layer and the third metal layer and spaced apart from each other.
